(19) United States
(12) Patent Application Publication
(10) Pub. No.: US 2008/0100374 A1
(43) Pub. Date: May 1, 2008

(54) Programmable filters and methods of operation thereof

(75) Inventors: Yannis Papananos, Marousi (GR); Yannis Tsividis, New York, NY (US)

Correspondence Address: BLAKELY SOKOLOFF TAYLOR & ZAFMAN, 1279 OAKMEAD PARKWAY, SUNNYVALE, CA, 94085-4040, US

(73) Assignee: Theta Microelectronics, Inc.

(21) Appl. No.: 11/590,599

(22) Filed: Oct. 30, 2006

(51) Int. Cl. H03B 1/00

(52) U.S. Cl. 327/553

(57) ABSTRACT

Programmable filters are used for the purpose of changing the filter cutoff frequency as may be necessary for the operation of a wireless transmitter or receiver. Frequencies may be changed by selecting a desirable value of a capacitor and/or a resistor. The programmable filter controls the frequency according to the disclosed method. Furthermore, in order to reduce the area consumed by the programmable filter a three-dimensional layout is used. In accordance with the disclosed invention it is possible to program the input of the programmable filter to have a higher or lower input resistance as may be required while maintaining the desired programmed cutoff frequency by switching the respective capacitors in a capacitor bank, thereby combining the elements needed for frequency programmability and input impedance level selection.

### BACKGROUND OF THE INVENTION

1. Field of the Invention

The present invention relates generally to programmable filters, and more specifically relates to programmable cut-off or center frequency filters.

2. Prior Art

The use of operational amplifiers for the purpose of creating a variety of low-pass, high-pass and band-pass filters is well known in the art. Referring to FIG. 1, there is shown a simple integrator 100, also known in the art as the Miller integrator. The integrator is comprised of an operational amplifier 110, a resistor 120 connected to the inverting input of operational amplifier 110, and a capacitor 130 providing a feedback path from the output to the inverting input of operational amplifier 110. The characteristics of integrator 100, i.e., the specific corner frequency of integrator 100, depend on the values of resistor 120 and capacitor 130.

For the purpose of providing a plurality of corner frequencies, it is customary to connect one or more additional capacitors, each in series with a switch, to enable capacitor connections in parallel to capacitor 130. Such a modified Miller integrator 200 is shown in FIG. 2. As a result, by switching switch 235 to a connecting position, capacitor 230-B is connected in parallel to capacitor 230-A. It is well known in the art that the total capacitance of capacitors connected in parallel is the sum of the capacitance of each of capacitors 230-A and 230-B. In another prior art embodiment, frequencies are adjusted by the use of connecting additional resistors through switches, such as shown in FIG. 3. In some embodiments, and in particular MOSFET-C filters, the ohmic resistors are implemented by means of MOS transistors. These provide for both the ohmic resistance and a switch in a single device. In the case where the capacitor bank is implemented using metal-insulator-metal implementation, the overall area of the filters is significantly impacted by the combined areas of the operational amplifiers and the capacitor bank, as shown schematically in FIG. 8. Specifically, capacitor bank 810 occupies one area of the layout and the operational amplifiers 820 occupy another area of the layout, while the MOS portion 830, which may further contain the MOS resistors, occupy a third area of the layout. Prior art solutions are deficient in providing a constant cutoff frequency of the programmable filter when there is a need to change the input resistance, for example for the purpose of controlling the signal-to-noise ratio. Specifically noted are “Adaptive analog IF signal processor for a wide-band CMOS wireless receiver,” by Behbahani et al., IEEE Journal of Solid-State Circuits, vol. 36, pp. 1205-1217, August 2001 (hereinafter “Behbahani”), and “Dynamically power-optimized channel-select filter for zero-IF GSM”, by Ozgun et al., Digest, IEEE International Solid-State Circuits Conference, pp. 504, 505 and 613, San Francisco, February 2005 (hereinafter “Ozgun”.

It would therefore be advantageous to provide a programmable filter configured to enable frequency programmability, while at the same time achieving a desired input resistance, and it would be further desirable if the elements required for these two purposes could be combined. It would be further advantageous if it would be possible to reduce the area occupied by such a filter.

### BRIEF DESCRIPTION OF THE DRAWINGS

FIG. 1 is a schematic diagram of a Miller integrator used for a filter application (prior art).

FIG. 2 is a schematic diagram of a Miller integrator of a programmable filter having a plurality of capacitors connected in parallel by means of switches (prior art).

FIG. 3 is a schematic diagram of a Miller integrator of a programmable filter having a plurality of capacitors connected in parallel by means of switches and a plurality of resistors connected in parallel by means of switches (prior art).

FIG. 4A is a schematic drawing of a first type of a capacitor bank in accordance with the disclosed invention.

FIG. 4B is a schematic drawing of a second type of a capacitor bank in accordance with the disclosed invention.

FIG. 5A is a schematic drawing of a first type of a resistor bank in accordance with the disclosed invention.

FIG. 5B is a schematic drawing of a second type of a resistor bank in accordance with the disclosed invention.

FIG. 5C is a schematic drawing of a resistor bank in accordance with the disclosed invention using MOS devices for combined switches and resistors.

FIG. 6 is a schematic diagram of a Miller integrator of a programmable filter designed in accordance with the disclosed invention.

FIG. 7A shows an exemplary capacitor bank switch table operable in accordance with the disclosed invention for a nominal input resistance.

FIG. 7B shows an exemplary capacitor bank switch table operable in accordance with the disclosed invention for an increased input resistance.

FIG. 8 is a top-level view of the layout of a filter having a plurality of operational amplifiers and capacitor banks (prior art).

FIG. 9 is a top level-view of the layout of a filter having a plurality of operational amplifiers and a capacitor bank laid out in accordance with the disclosed invention.

FIG. 10 is a layout of a chip having a programmable filter laid out in accordance with the disclosed invention.

FIG. 11 is a cross section illustrating the lower level interconnect metal layers and the two-upper metal layers forming the capacitor bank.

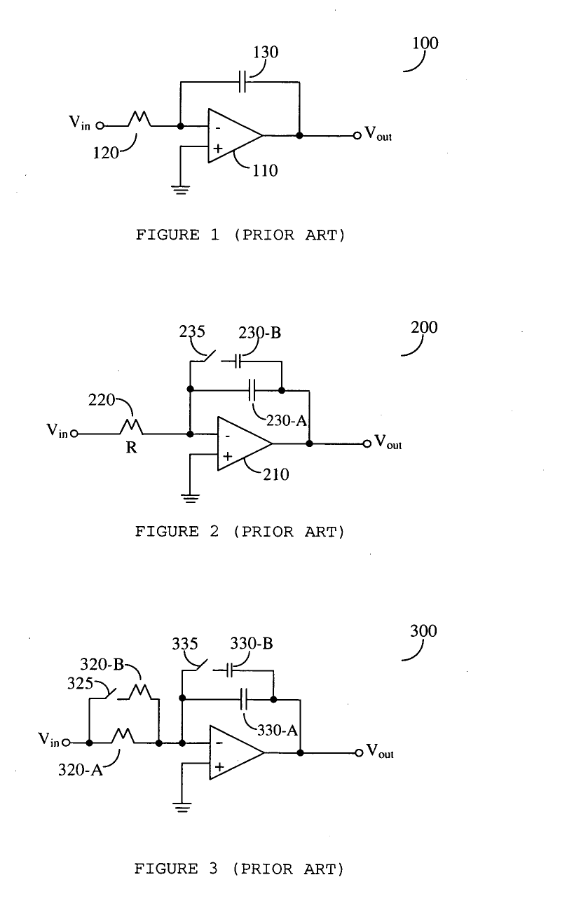

### DETAILED DESCRIPTION OF THE PREFERRED EMBODIMENTS

For the purpose of overcoming the deficiencies of the prior art, a plurality of capacitors are used in a capacitor bank in a negative feedback loop of an amplification means, for example an operational amplifier, each capacitor of the capacitor bank being capable of being either connected or disconnected to the feedback loop by means of a respective switch. In addition, a resistor bank is connected to the inverting input of the amplification means of the filter, each resistor being capable of being connected or disconnected from the circuit input by means of a respective switch. In one embodiment of the disclosed invention all but one of the capacitors and all but one of the resistors are connected to a switch while one capacitor and one resistor are permanently connected. All switches are connected to the virtual ground of the op amp, thus minimizing variations of the gate-source and/or gate-drain voltages, which would otherwise cause a variation in switch resistance and would result in signal distortion. The switches are operative under control means, the control means being capable of programming the cutoff frequency while providing the desired input resistance of the filter. The setting of the input resistance may be necessary, for example, for the purpose of controlling signal-to-noise ratio and impact thereof. Therefore the disclosed invention enables frequency programmability and impedance level selection. In another embodiment of the disclosed invention all capacitors and all resistors are connected in series with a switch. A control unit is used to ensure that at least one capacitor and at least one resistor are always connected.

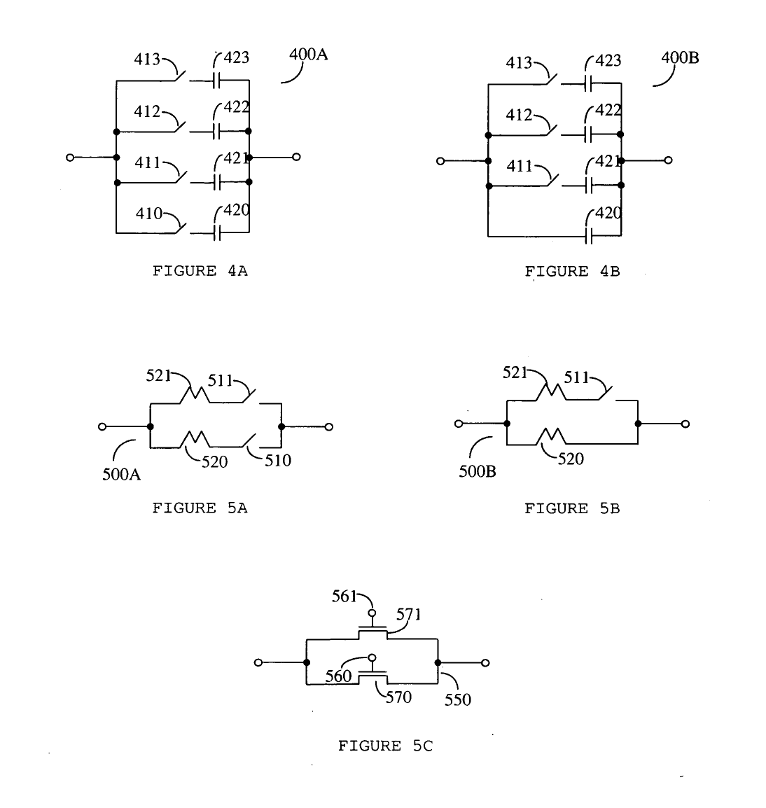

In accordance with the disclosed invention, a capacitor bank, such as one of the capacitor banks 400A and 400B shown in FIGS. 4A and 4B respectively, is used in the negative feedback loop. Capacitor bank 400A comprises a plurality of capacitors capable of parallel connection by means of respective switches. In the exemplary and non-limiting FIG. 4A, there are shown four capacitors 420, 421, 422, and 423, each having a respective switch 410, 411, 412, and 413. Each of the plurality of switches may be turned ‘on’, i.e., in a conducting position, or ‘off’, i.e., in a non-conducting position, independently of any other of the plurality of switches of capacitor bank 400A. In another embodiment of the disclosed invention, and as shown in more detail below, the capacitor bank 400B shown with respect to FIG. 4B is used in the feedback loop. In comparison to the exemplary embodiment 400A, a switch, for example switch 410, may be permanently in the “on” position, or replaced by a shunt, as in 400B. Furthermore, in accordance with the disclosed invention, a resistor bank, such as one of the resistor banks 500A or 500B shown in FIGS. 5A and 5B respectively, and used to connect the input of the filter to the amplification means. A person skilled-in-the-art would note that for a MOSFET-C filter implementation, the ohmic resistors, for example resistors 520 and 521, are replaced by MOS transistors, for example MOS transistors 570 and 571 shown in FIG. 5C, which further provide the respective switching means equivalent to switches 510 and 511, through the control of the gate voltage, for example at gates 560 and 561, of each of the MOS transistors. In one embodiment of the disclosed invention a MOS resistor, for example MOS resistor 570, may be permanently “on”, by providing the desired voltage at gate 560. It is to be understood that, although the circuits are shown here unbalanced, a fully-balanced configuration would be required in order to cancel MOSFET nonlinearities in a MOSFET-C configuration. Such fully-balanced circuits maybe found in U.S. Pat. No. 7,049,875 entitled “One-pin automatic tuning of MOSFET resistors”, assigned to common assignee and which is hereby incorporated by reference for all the useful information it may contain.

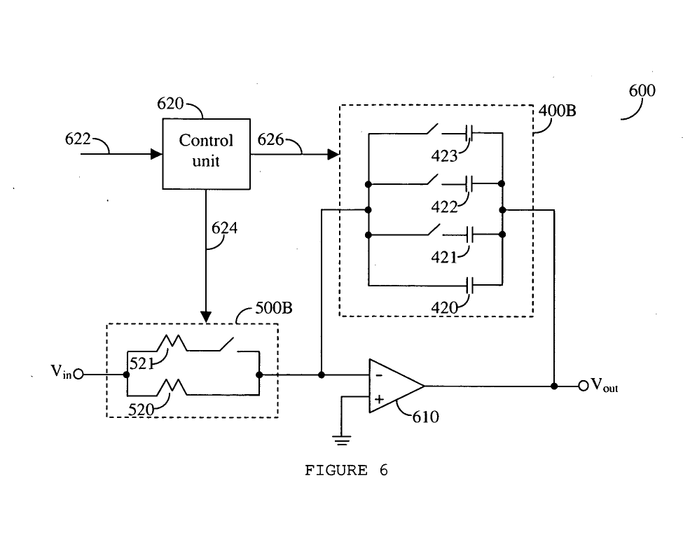

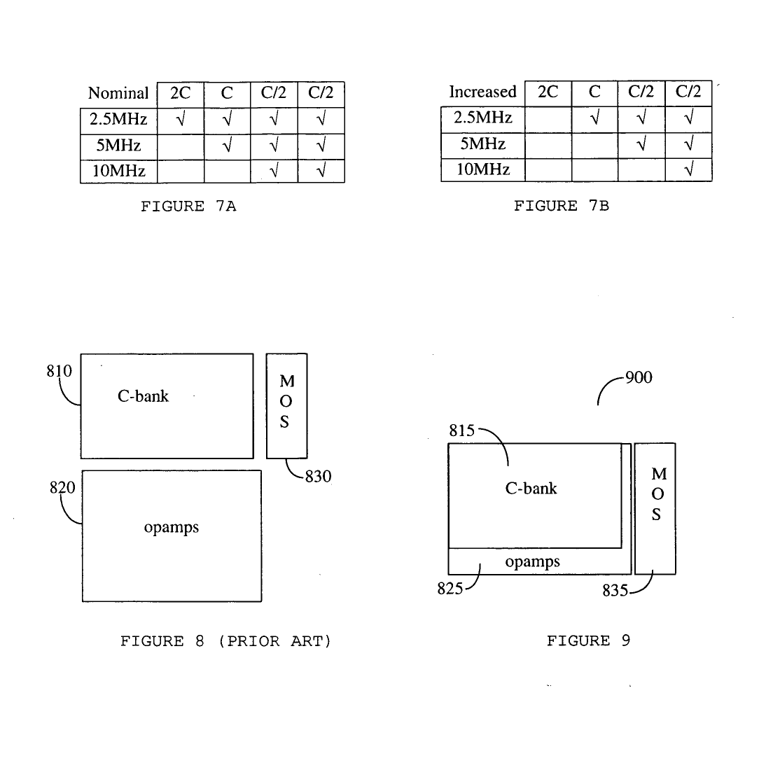

Reference is now made to FIG. 6 where an exemplary and non-limiting schematic diagram 600 of a Miller integrator of a programmable filter is shown. Amplification means is implemented by using an operational amplifier 610 having the non-inverting input grounded. The output of operational amplifier 610 is connected to the inverting input of operational amplifier 610 by means of capacitor bank 400, where one capacitor is permanently connected in the feedback loop. The input of the programmable filter is connected to the inverting input of operational amplifier 610 by means of resistor bank 500, where one resistor is permanently connected in the input path. The switches of both capacitor bank 400, regardless whether for example 400A or 400B, and resistor bank 500, regardless whether for example 500A, 500B or 500C, are controlled, for example, by a control unit 620. The specific operation of control unit 620 is explained in more detail below. It should be further noted that if capacitor bank of the type 400A and/or a resistor bank of type 500A are used, it is essential to ensure that a conducting path exists for at least a capacitor and/or at least a resistor, that is provided by means of control unit 620. Specifically, in a preferred embodiment control unit 620 is enabled to ensure that at least a capacitor of capacitor bank 400A is connected in the feedback loop, and/or at least a resistor of resistor bank 500A is connected in the input path.

Merely for the purpose of illustration, a particular application of the disclosed invention is presented. However, this example should not be construed as limiting the scope of the disclosed invention. A person skilled-in-the-art would readily note that the characteristic frequencies (cutoff frequencies for low-pass or high-pass filters, or center frequencies for bandpass filters) of active RC filters are inversely proportional to resistance-capacitance products. Assume three distinct cutoff frequencies are required from programmable filter 600, for example 2.5, 5 and 10 MHz. Capacitor bank 400B is comprised of a group of capacitors having respective exemplary values of C/2, C/2, C, and 2C, for capacitors 420, 421, 422, and 423 respectively, as shown for the capacitor bank 400B in FIG. 4B as may be used in the circuit of FIG. 6. Such binary weighting is discussed in “A segmented u-255 law PCM voice encoder utilizing NMOS technology”, by Tsividis et al., IEEE Journal of Solid State Circuits, vol. SC-11, no. 6, pp. 740-747, December 1976. For a known input resistance, discussed in more detail below, to achieve a 2.5 MHz filter the switches are closed to create a total capacitance of 4C; for a 5 MHz filter the 2C capacitance is used; and, for a 10 MHz capacitance the C capacitance is used. Now, for the purpose of achieving the goals of the disclosed invention, described hereinabove, resistor bank 500 is comprised of a plurality of resistors connected in parallel, for example resistors 520 and 521 of FIG. 5A as used in FIG. 6, each having a resistive value of R, and where resistor 520 is permanently connected in the input path. As a result, in this case, two distinct impedance levels are available: R and R/2. The value of R/2 is used for the nominal impedance level, while the resistance R may be used to support a higher input resistance. Hence, in the example above, the given resistance value is for the nominal impedance. If the higher input resistance is desired, then switching of the switches of both resistor bank 500 and capacitor bank 400 are required, performed, for example, under the control of control unit 600. For merely illustrative purposes, the following example is now provided for a programmable filter having a cutoff frequency of 2.5 MHz. For nominal operation switch 511 is closed to achieve an effective input resistance of R/2. The capacitance required is 4C and therefore switches 411, 412, and 413 are all closed, causing the four capacitors 420 through 423 to be connected in parallel. To switch to the higher input resistance mode of operation, the switch 511 must be opened, thereby increasing the input resistance to a value of R. It is further necessary to reduce the capacitance in the feedback loop in order to maintain the desired cutoff frequency, i.e.., changing the effective capacitance of capacitor bank 400 from 4C to 2C, thereby maintaining the same resistance-capacitance product. To achieve this, switches 411 and 412 are kept in the closed position while switch 413 is caused to be in the open position, leaving an effective capacitance of 2C comprising of C/2, C/2 and C capacitors connected in parallel in the feedback loop.

In another illustrative example the target frequency cutoff is 10 MHz, and hence for nominal input resistance the switches of resistor bank 500 are configured to provide an input resistance of R/2 (i.e., one switch in the closed position). The cutoff frequency of a 10 MHz filter requires a capacitance of C, which can be achieved in accordance with the disclosed invention by having switch 411 in the closed position such that capacitors 420 and 421 are connected in parallel, and as each has a value of C/2, the total feedback capacity is C. When it is desired to move to the higher input resistance mode the input resistance is increased by switching switch 511 of the resistor bank 500 to the open position, thereby causing the input resistance to increase to R. In order to maintain the desired cutoff frequency of 10 MHz, the capacitance must be reduced by half, which may be achieved by opening the closed switch 421 of capacitor bank 400. As a result there is now only a single capacitor in the feedback loop, namely capacitor 420, with a value of C/2.

The above examples show only the portion of the Miller integrator, implemented in accordance with the disclosed invention, rather than a full filter, for clarity purposes, and should not be viewed as limiting the disclosed invention. Control unit 620 may be further configured to be operative in response to a signal-to-noise measurement that may require the increase or decrease of the input resistance of the filter without changing the cutoff frequency, as discussed in Behbahani and in Ozgun.

A person skilled-in-the-art would readily realize that the disclosed invention may be generalized for more cutoff frequencies and input resistances to the Miller integrator of a programmable filter. Hence, capacitor bank 400 should be viewed as being comprised of a plurality of capacitors and respective switches, and resistor bank 500 should be viewed as being comprised of a plurality of resistors and respective switches. It should be further noted that these are not limited to binary-weighted (power of two) values and in fact other, more complex combinations may be materialized, and are specifically included herein as part of the disclosed invention. A person-skilled-in-the art would further note that in the circuit shown herein the plurality of resistors, for example resistors 520 and 521, of resistor bank 500 may be used to further determine the specific cutoff frequency of the programmable filter. Furthermore, the circuit may be used in other analog circuits that benefit from the ability to maintain a cutoff frequency while changing the desired input resistance. The amplifier shown is for illustration purposes only and a plurality of amplifiers may also be used without departing from the spirit of the disclosed invention.

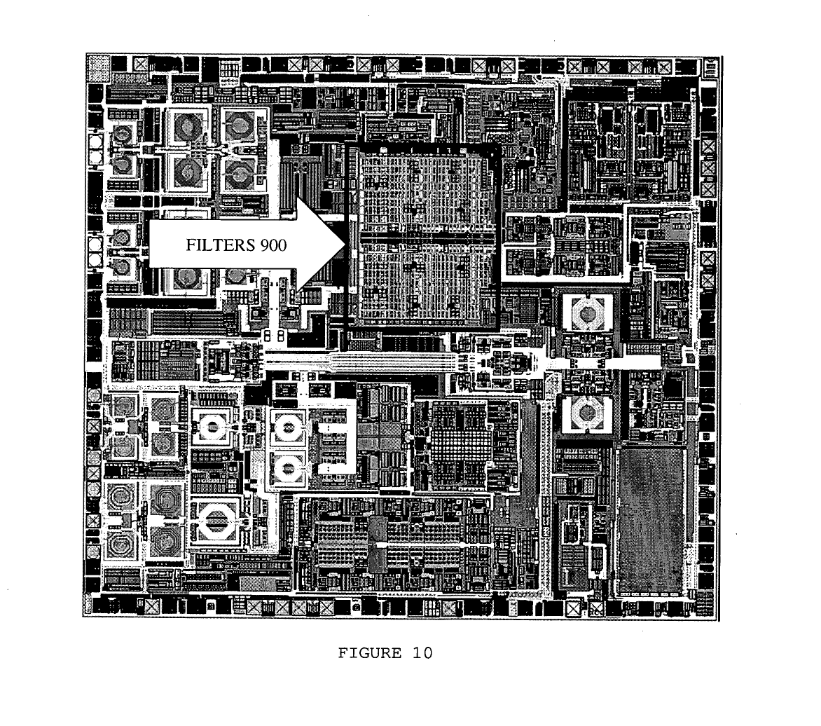

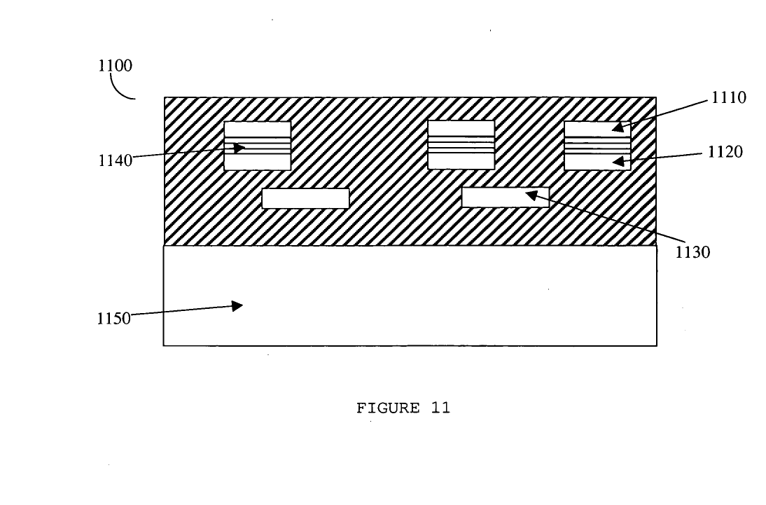

In FIG. 8, a traditional layout of the filter is shown. A common problem of programmable filters is the need to have a plurality of metal-insulator-metal (MIM) based capacitors that occupy significant layout area. In order to overcome the deficiency thereof a method of layout is used to overcome this problem, as shown in FIG. 9. Firstly, the wiring (interconnect) internal to the operational amplifier circuits, for example operational amplifier 610 shown in FIG. 6, employ only bottom-level metals, ensuring that at least two higher levels of metals are still available above the inter routing of the operational amplifiers. Secondly, the capacitor bank 815, respective of, for example, capacitor bank 400, is placed over the area of operational amplifiers 825, respective of, for example, operational amplifier 610, and as further shown in FIG. 9, showing the programmable filter 900 implemented in accordance with the disclosed invention. As a result, significant chip area is saved. Comparison of a traditional channel select filter layout resulted in an area of 2.05 mm² in comparison to an area of 1.14 mm² using the “3-D” layout approach disclosed herein. Measurement results on the 3-D structure did not reveal any deviation from the traditional approach employed for the same filter. Specifically, FIG. 10 shows a layout of a chip with a programmable filter 900 laid out in accordance with the disclosed invention. FIG. 11 illustrates a cross section 1100 showing the lower level interconnect metal layers, for example metal layer 1130, and the two patterned upper metal layers 1110 and 1120 separated by a deposited dielectric layer 1140, together forming the capacitor bank. Below lower level interconnect metal layers there resides the active area 1150 in which the MOS transistors, for example those forming the operational amplifiers 825, are shown. For simplicity of the illustration the details of the MOS transistors that form the operational amplifiers are not shown.

While certain preferred embodiments of the present invention have been disclosed and described herein for purposes of illustration and not for purposes of limitation, it will be understood by those skilled in the art that various changes in form and detail may be made therein without departing from the spirit and scope of the invention.

What is claimed is:

1. A programmable filter comprising:
amplifier;
a capacitor bank comprised of a plurality of capacitors, a first of said capacitors being either permanently connected in said capacitor bank or being connected or disconnected from said capacitor bank by a respective switch, each other of said plurality of capacitors being connectable in parallel to said first capacitor by being connected or disconnected from said capacitor bank by a respective switch, said capacitor bank being connected in a negative feedback path of said amplifier;
a resistor bank comprised of a plurality of resistors, a first of said resistors being either permanently connected in said resistor bank or being connected or disconnected from said resistor bank by a respective switch, each other of said plurality of resistors being connectable in parallel to said first resistor by being connected or disconnected from said resistor bank by a respective switch, said resistor bank being coupled to the input of said amplifier to provide an input resistance for said programmable filter; and,
a control unit coupled to control said switches of said capacitor bank and said resistor bank to program the cutoff frequency with any of a set of different input resistances of the programmable filter, selected by control of said switches in said resistor bank.

2. The programmable filter of claim 1, wherein said control unit is configured to enable frequency programmability and input impedance level selection.

3. The programmable filter of claim 1, wherein said control unit is configured to at least: a) control the switches in the resistor bank to provide a second input resistance different from a first input resistance to increase the input resistance of the programmable filter; and, b) control the switches in the capacitor bank to cause the selection of a second effective capacitance of said capacitor bank to maintain the programmed cutoff frequency as provided by said first input resistance and a first effective capacitance of said capacitor bank.

4. The programmable filter of claim 1, the programmable filter being implemented as a monolithic semiconductor chip.

5. The programmable filter of claim 4, wherein said amplifier is implemented in said monolithic semiconductor device using lower-level metal layers, leaving at least two upper-level patterned metal layers separated by an insulator layer to form metal-insulator-metal type capacitors, said capacitors being placed over said amplification means to provide said capacitor bank.

6. The programmable filter of claim 1, wherein at least a resistor and respective switch of said resistors in said resistor bank is implemented as a MOS transistor.

7. The programmable filter of claim 6, wherein said programmable filter is a MOSFET-C having a balanced configuration.

8. The programmable filter of claim 1, wherein the capacitor bank is comprised of four capacitors, said first capacitor having the value of C/2, a second capacitor having the value of C/2, a third capacitor having the value of C, and a fourth capacitor having the value of 2C, and wherein the resistor bank is comprised of said first resistor and a second resistor, each having a value of R.

9. The programmable filter of claim 8, wherein a high cutoff frequency for a high input resistance is achieved by opening the respective switches of said second, third and fourth capacitors, and opening the switch of said second resistor.

10. The programmable filter of claim 9, wherein half of said high cutoff frequency for a high input resistance is achieved by also closing the respective switch of said second capacitor.

11. The programmable filter of claim 10, wherein a fourth of said high cutoff frequency for a high input resistance is achieved by also closing the respective switch of said third capacitor.

12. The programmable filter of claim 8, wherein the high cutoff frequency for a low input resistance is achieved by closing the respective switch of said first and said second capacitor and closing the switch of said second resistor and opening all other switches.

13. The programmable filter of claim 12, wherein half of said high cutoff frequency for a low input resistance is achieved by also closing the respective switch of said third capacitor.

14. The programmable filter of claim 13, wherein one fourth of said high cutoff frequency for a low input resistance is achieved by further closing the respective switch of said fourth capacitor.

15. The programmable filter of claim 1, wherein said control unit is enabled to ensure that at all times said first of said capacitors is connected in the feedback loop of said amplification means.

16. The programmable filter of claim 1, wherein said control unit is enabled to ensure that at all times said first of said resistors is connected in the input path to said amplification means.

17. A programmable analog circuit comprising a differential amplifier, a capacitor bank connected between the output of said differential amplifier and the inverting input of said differential amplifier, a resistor bank coupled to said inverting input of said differential amplifier, and a control circuit enabled to control said capacitor bank and said resistor bank by maintaining a programmed cutoff frequency when changing an input resistance to said programmable analog circuit by changing an effective resistance of said resistor bank.

18. The programmable analog circuit of claim 17, wherein said capacitor bank is comprised of a plurality of capacitors that may be connected in parallel by opening or closing a switch that is associated with each of said plurality of capacitors, the control of the switches being performed by said control circuit.

19. The programmable analog circuit of claim 17, wherein said resistor bank is comprised of a plurality of resistors that may be connected in parallel by opening or closing a switch that is associated with each of said plurality of capacitors, the switches being controlled by said control circuit.

20. The programmable analog circuit of claim 17, where said control circuit is configured to at least: a) cause the selection of a second effective resistance of said resistor bank that is different from a first effective resistance for the purpose of achieving a higher input resistance to the programmable analog circuit; and, b) cause the selection of a second effective capacitance from said capacitor bank that maintains the same programmed cutoff frequency obtained using the said first effective resistance and a first effective capacitance.

21. The programmable analog circuit of claim 17, where said control circuit is further configured to at least one of: a) ensure that at all times at least a capacitor of said capacitor bank is connected in the feedback loop of said amplification means; and, b) ensure that at all times at least a resistor of said resistor bank is connected in the input path to said amplification means.

22. The programmable analog circuit of claim 17, the programmable analog circuit being implemented as a monolithic semiconductor.

23. The programmable analog circuit of claim 22, wherein said differential amplifier is implemented in said monolithic semiconductor device using lower-level metal layers, leaving at least two upper-level patterned metal layers separated by an insulator layer to form metal-insulator-metal type capacitors, said capacitors being placed over said amplification means to provide said capacitor bank.
